(19) United States
(12) Patent Application Publication
(10) Pub. No.: US 2023/0266377 A1
(43) Pub. Date: Aug. 24, 2023

(54) ELECTRICAL DEVICE FOR ELECTRICAL POWER MONITORING AND ANALYSIS AT A DATA HALL RACK

(71) Applicant: Meta Platforms, Inc., Menlo Park, CA (US)

(72) Inventors: Octavio Valdez, Albuquerque, NM (US); Ivan C. Madrid, JR., Rio Rancho, NM (US); Mark Ferda, Aurora, CO (US)

(21) Appl. No.: 17/584,198

(22) Filed: Jan. 25, 2022

(51) Int. Cl. G01R 31/08

(52) U.S. Cl. CPC G01R 31/085

(57) ABSTRACT

A system having an electrical device for electrical power monitoring and analysis is disclosed. The system may enable electrically connecting of a measurement component of an electrical device to a plurality of electrical ports via a power line of a data center to detect one or more electrical signals. The electrical device, the plurality of electrical ports and the power line may be embodied within a non-metallic enclosure configured to reduce electromagnetic interference within the non-metallic enclosure. The system may measure a quantity of the electrical signals via the measurement component. The system may determine, based on analyzing the quantity of the electrical signals, one or more troubleshooting actions associated with the power line of the data center.

### TECHNOLOGICAL FIELD

Exemplary embodiments of this disclosure may relate generally to power electronics, and more particularly to methods, apparatuses and computer program products for monitoring electrical power supplied to computer server racks (e.g., in a data center, industrial setting, etc.).

### BACKGROUND

Organizations often employ data centers to manage their data processing and other computing needs, e.g., cloud computing, large-scale application services, or data services in information teleology (IT) operations. A data center typically houses many racks of servers, which together perform the processing tasks that a single machine may be unable to perform. The role of a data center is often critical to an organization, and downtime of a data center may result in severe consequences to the organization and to others who may rely on the data center. One of the infrastructural challenges of a data center is powering the server racks in the data center. For example, server racks may be negatively impacted by potential power surges and power outages ( e.g., including black outs or brown outs).

Due to potentially large numbers of server racks and a potentially large number of branching circuits sometimes involved in a power system, determining a particular location or cause of a failure in such a system may prove to be problematic, possibly causing a significant amount of time and expense to identify accurately. Accordingly, monitoring of a data center’s environment and equipment may be crucial to maintaining a properly functioning data center. Monitoring may include keeping track of a power voltage level of a power supply, a power current level of a power supply, a temperature, a humidity level, or any combination thereof. Existing monitor systems tend to be difficult to install, particularly during normal operations at a single rack server level. Complicated wiring of the monitor sensors and monitor stations may increase the cost of installation of these traditional monitor systems. There is a lack of specific solutions to resolve these challenges adequately.

In view of the foregoing, it may be beneficial to provide a device that may monitor, record and analyze electrical power disturbances for a single rack server level during normal operations.

### BRIEF SUMMARY

Exemplary embodiments are described for electrical power monitoring and analysis. In this regard, an external electrical device may monitor, record, and analyze one or more electrical power disturbances, e.g., for a single rack server level during normal operations. Moreover, the external electrical device may be installed without any exposure to electrical hazard (e.g., without the need for specialized equipment, without wire stripping or tapping, etc.). For example, the external electrical device may be installed in a user-friendly manner by connecting (e.g., via an extension cord) the external electrical device to the power source (e.g., a tap box) and connecting the device to a load (e.g., a server rack). Data may be analyzed by the external electrical device and/or may be transmitted (e.g., to a computer or cloud computing system) for analysis. According to some exemplary embodiments, one or more faults may be identified and one or more actions may be performed based on the one or more identified faults.

In one example embodiment, a method for an electrical device performing electrical power monitoring and analysis is provided. The method may include electrically connecting a measurement component of an electrical device to electrical ports via a power line of a data center to detect one or more electrical signals. The electrical device, the electrical ports and the power line may be embodied within a non-metallic enclosure configured to reduce electromagnetic interference within the non-metallic enclosure. The method may further include measuring a quantity of the electrical signals via the measurement component. The method may further include determining, based on analyzing the quantity of the electrical signals, one or more troubleshooting actions associated with the power line of the data center.

In another example embodiment, a system for performing electrical power monitoring and analysis is provided. The system may include a device including one or more processors and a memory including computer program code instructions. The memory and computer program code instructions are configured to, with at least one of the processors, cause the device to at least perform operations including measuring, by a measurement component of the device, a quantity of one or more electrical signals, wherein the measurement component of the device is electrically connected to electrical ports via a power line of a data center to detect the one or more electrical signals. The device, the electrical ports and the power line may be embodied within a fiberglass enclosure configured to reduce electromagnetic interference within the fiberglass enclosure. The memory and computer program code are also configured to, with the processor, cause the device to determine, based on analyzing the quantity of the electrical signals, one or more troubleshooting actions associated with the power line of the data center.

In yet another example embodiment, a computer program product for an electrical device performing electrical power monitoring and analysis is provided. The computer program product includes at least one computer-readable storage medium having encoded computer-executable program code instructions stored therein. The computer-executable program code instructions may include program code instructions configured to measure, by a measurement component of an electrical device, a quantity of one or more electrical signals, wherein the measurement component of the electrical device is electrically connected to electrical ports via a power line of a data center to detect the one or more electrical signals. The electrical device, the electrical ports and the power line may be embodied within a non-metallic enclosure configured to reduce electromagnetic interference within the non-metallic enclosure. The computer program product may further include program code instructions configured to determine, based on analyzing the quantity of the electrical signals, one or more troubleshooting actions associated with the power line of the data center.

In yet another example embodiment, a method for monitoring, recording, and analyzing one or more electrical power disturbances is provided, e.g., for a single rack server level during normal operations. The method may include installation of an external electrical device minimizing any exposure to electrical hazard (e.g., without the need for specialized equipment, without wire stripping or tapping, etc.). For example, the method may include connecting (e.g., via an extension cord) the external electrical device to the power source (e.g., a tap box) and connecting the device to the load (e.g., a server rack). According to some exemplary embodiments, the method may include analysis and/or transmission of the recorded data. According to some exemplary embodiments, the method may include identifying one or more faults and one or more actions may be performed based on the one or more identified faults.

In another example embodiment, a computer program product for monitoring, recording, and analyzing one or more electrical power disturbances is provided, e.g., for a single rack server level during normal operations. The computer-executable program code instructions may include program code instructions configured to receive data and analyze the received data. Moreover, the computer-executable program code instructions may include program code instructions configured to identify one or more faults and identify one or more remedial actions based on the one or more identified faults.

Additional advantages will be set forth in part in the description which follows or may be learned by practice. The advantages will be realized and attained by means of the elements and combinations particularly pointed out in the appended claims. It is to be understood that both the foregoing general description and the following detailed description are exemplary and explanatory only and are not restrictive, as claimed.

### BRIEF DESCRIPTION OF THE DRAWINGS

FIG. 1 is a diagram of an exemplary system for monitoring electrical power.

FIG. 2 is a diagram of an exemplary external electrical device for electrical power monitoring and analysis in accordance with an exemplary embodiment.

FIG. 3 is a schematic diagram of an exemplary external electrical device for electrical power monitoring and analysis in accordance with an exemplary embodiment.

FIG. 4 is a flow chart of an exemplary method for monitoring electrical power in accordance with an exemplary embodiment.

FIG. 5 is a flow chart of an exemplary method for a device performing electrical power monitoring and analysis, in accordance with an exemplary embodiment.

FIG. 6 is a diagram of an exemplary computer system in accordance with an exemplary embodiment.

The figures depict various embodiments for purposes of illustration only. One skilled in the art will readily recognize from the following discussion that alternative embodiments of the structures and methods illustrated herein may be employed without departing from the principles described herein.

### DETAILED DESCRIPTION

Some embodiments of the present invention will now be described more fully hereinafter with reference to the accompanying drawings, in which some, but not all embodiments of the invention are shown. Indeed, various embodiments of the invention may be embodied in many different forms and should not be construed as limited to the embodiments set forth herein. Like reference numerals refer to like elements throughout. As used herein, the terms “data,” “content,” “information” and similar terms may be used interchangeably to refer to data capable of being transmitted, received and/or stored in accordance with embodiments of the invention. Moreover, the term “exemplary”, as used herein, is not provided to convey any qualitative assessment, but instead merely to convey an illustration of an example. Thus, use of any such terms should not be taken to limit the spirit and scope of embodiments of the invention.

As defined herein a “computer-readable storage medium,” which refers to a non-transitory, physical or tangible storage medium (e.g., volatile or non-volatile memory device), may be differentiated from a “computer-readable transmission medium,” which refers to an electromagnetic signal.

References in this description to “an embodiment”, “one embodiment”, or the like, may mean that the particular feature, function, or characteristic being described is included in at least one embodiment of the present invention. Occurrences of such phrases in this specification do not necessarily all refer to the same embodiment, nor are they necessarily mutually exclusive.

It is to be understood that the methods and systems described herein are not limited to specific methods, specific components, or to particular implementations. It is also to be understood that the terminology used herein is for the purpose of describing particular embodiments only and is not intended to be limiting.

Some exemplary embodiments may provide an electrical device that may monitor, record, and analyze one or more electrical power disturbances, for example, for a single rack server level. The electrical device may be installed with minimal exposure to electrical hazard, for example, without the need for specialized equipment, without wire stripping or tapping, etc. For example, the electrical device may be installed in a user-friendly manner by connecting the electrical device to the power source such as, for example, a tap box and connecting the electrical device to a load. Data may be analyzed by the electrical device and/or may be transmitted, for example, to a computing device or cloud computing system for analysis. One or more faults may be determined, based on the data, and one or more actions may be performed based on the one or more determined faults.

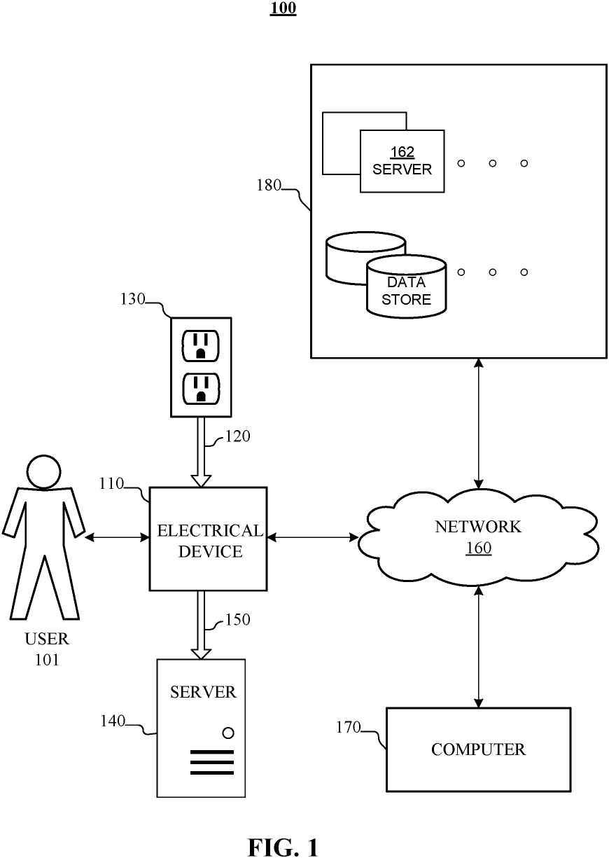

Referring to FIG. 1, a diagram illustrating an example of a physical environment 100 including an external electrical monitoring device 110 is provided. The external electrical monitoring device 110 may be an assembly of devices and components for measuring one or more physical properties, such as electric current, electric voltage, electric power, harmonics, or any combination thereof.

The external electrical monitoring device 110 may enable easy deployment and analysis, e.g., at a data hall rack in the data center. According to some embodiments, the external electrical monitoring device 110 may be a device for measuring, tracking, and/or analyzing one or more physical quantities (e.g., of physical environment 100) and reporting the one or more physical quantities back to a device associated with a user (e.g., user 101), display, central monitoring station, e.g., computer 170 (also referred to herein as user device 170) and/or server 180, etc. via a network connection to one or more networks (e.g., network 160). The external electrical monitoring device 110 may also proactively modify, or provide instructions/insight to modify, the physical environment 100 or equipment based on the tracked physical quantities. For example, the external electrical monitoring device 110 may be used to track and manage power quality to a server rack.

According to some exemplary embodiments, the external electrical monitoring device 110 may be coupled (e.g., quickly and easily) to a power source 130 (e.g., a tap box) and a load 140, also referred to herein as server 140, (e.g., a server rack in a data center) for providing monitoring, analysis, and troubleshooting at various locations and for communicating information (e.g., via a display to user 101 or over network 160). Moreover, the external electrical monitoring device 110 may include one or more user interfaces, including one or more touch buttons, a touch display, a keyboard interface, wired or wireless connection to a remote interface, etc.

Conventional external electrical devices may be wired individually to power sources and loads, which may include performing manual connections to the power sources and loads. These manual connections often require accessing service panels, bare wires, etc., which may be time consuming, costly, and dangerous without strict adherence to electrical safety procedures. As such, these conventional external electrical devices may make it costly and difficult to troubleshoot power delivery to server racks in data centers or other industrial environments during normal usage.

Therefore, to allow ease of deployment of the external electrical monitoring device 110 to monitor power supply from power source 130 to a load 140, such as server racks, a mechanism to deploy external electrical monitoring device 110 is provided. This mechanism allows the external electrical monitoring device 110 to be connected to a power source 130 (e.g., a tap box) via user friendly plug and play connections. For example, the external electrical monitoring device 110 may include an input electrical connection 120 (e.g., permanently connected or removably connected) that may be compatible with a tap box such that the input electrical connection may be plugged into a tap box.

Similarly, the external electrical monitoring device 110 may include an output electrical connection 150 (e.g., permanently connected or removably connected) that is compatible with a server rack such that the load 140 (e.g., a server rack) may be plugged into the output electrical connection 150. Moreover, the case and connections of the external electrical monitoring device 110 may be inspected, tested, and certified by one or more recognized independent laboratories or organizations to ensure electrical safety. This approach may also allow the external electrical monitoring device 110 to be electrically coupled to the power source 130 (e.g., tap box) and load 140 (e.g., server rack) both quickly and safely. The external electrical monitoring device 110 coupled to the power source 130 and load 140, therefore, may monitor, track, analyze, and troubleshoot power delivery from the power source 130 to the load 140 (e.g., during the load’s normal usage). Moreover, the external electrical monitoring device 110 may provide a user interface and/or a communication channel to one or more external systems (e.g., user device 170 and/or server 180 via network 160).

According to some embodiments, the user device 170 and/or server 180 may comprise one or more computing devices, e.g., server 162 and memory device (e.g., data store 164), capable of receiving user input as well as transmitting and/or receiving data via the network 160. In one exemplary embodiment, a user device 170 may be a computer system, such as a desktop, a laptop computer, or a smart tablet. Alternatively, a user device 170 may be a device having computer functionality, such as a personal digital assistant (PDA), a mobile telephone, a smartphone or another suitable device. A user device 170 is configured to communicate via the network 160. In one embodiment, a user device 170 may execute an application allowing a user (e.g., user 101) of the user device 170 to interact with the external electrical monitoring device 110. For example, a user device 170 may execute a browser application to enable interaction between the user device 170 and the external electrical monitoring device 110 via the network 160. In another embodiment, a user device 170 may interact with the external electrical monitoring device 110 through an application programming interface (API) or a software development kit (SDK) running on a native operating system of the user device 170, such as for example a mobile operating system.

The user device 170 and/or server 180 may be configured to communicate via the network 160, which may comprise any combination of local area and/or wide area networks, using both wired and/or wireless communication systems. In one embodiment, the network 160 may use standard communications technologies and/or protocols. For example, the network 160 may include communication links using technologies such as Ethernet, 802.11, worldwide interoperability for microwave access (WiMAX), 3G, 4G, 5G, code division multiple access (CDMA), digital subscriber line (DSL), etc. Examples of networking protocols used for communicating via the network 160 may include multiprotocol label switching (MPLS), transmission control protocol/Internet protocol (TCP/IP), hypertext transport protocol (HTTP), simple mail transfer protocol (SMTP), and file transfer protocol (FTP). Data exchanged over the network 160 may be represented using any suitable format, such as, for example, hypertext markup language (HTML) or extensible markup language (XML). In some embodiments, all or some of the communication links of the network 160 may be encrypted using any suitable technique or techniques.

One or more external electrical monitoring device 110 may be coupled to the network 160 for communicating with the user device 170 and/or server 180. In one exemplary embodiment, an external electrical monitoring device 110 may provide content or other information for presentation via a user device 170. In other exemplary embodiments, external electrical monitoring device 110 may be an application provider communicating information describing applications for execution by a user device 170 or communicating data to user device 170 for use by an application executing on the user device 170. In various exemplary embodiments, a user 101 associated with a user device 170 may interact with the external electrical monitoring device 110 via the user device 170.

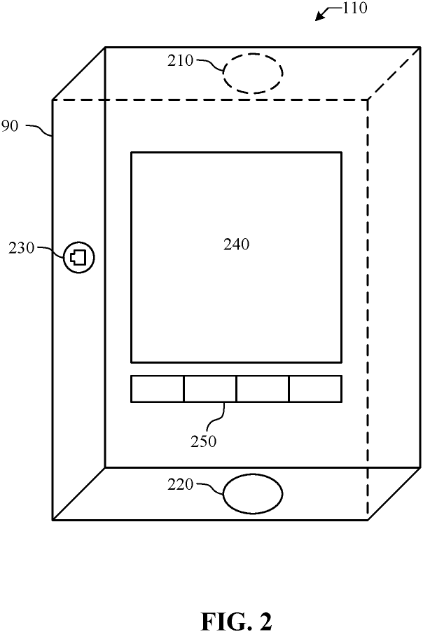

Referring to FIG. 2, a diagram illustrating an example of an external electrical monitoring device 110 is provided according to an exemplary embodiment. As illustrated, the external electrical device 110 may include: an enclosure 90, an input electrical connection 210, an output electrical connection 220, a user interface (e.g., display 240 and keypad 250), a network connection 230, and a processor 235. A power source (e.g., a tap box) may be coupled to the input electrical connection 210 and a power load (e.g., a server rack) may be coupled to the output electrical connection 220. The external electrical device 110 may include a measurement component. The external electrical monitoring device 110 may be coupled to the power source (e.g., power source 130) and the power load (e.g., load 140) by using compatible plugs with the power source and the power load, e.g., without any connection taps, wire stripping, electrical panel access, etc. The external electrical monitoring device 110 device may perform data collection, tracking, analysis, and troubleshooting and may transmit received or analyzed information by one or more wired or wireless network connections (e.g., via network connection 230).

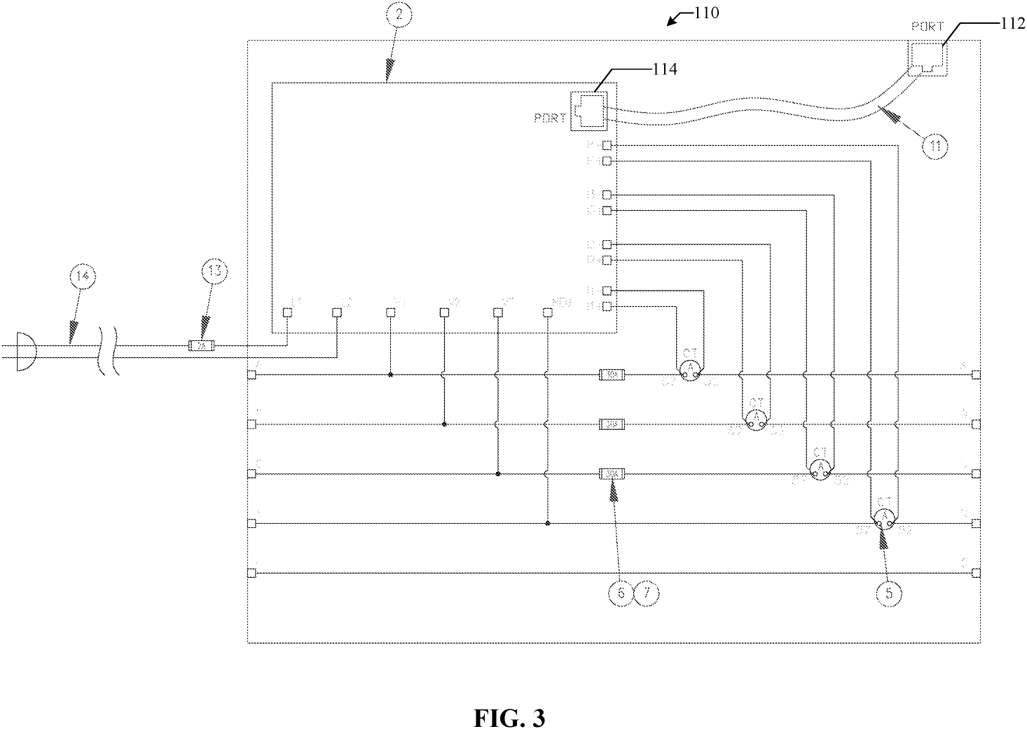

Referring to FIG. 3, a schematic diagram illustrating an example of external electrical monitoring device 110 is provided. According to some embodiments, the external electrical monitoring device 110 may be embodied/comprised within an enclosure 90 (e.g., enclosure 90 of FIG. 2). The enclosure 90 may be constructed of non-metallic material, e.g., to prevent any danger that may be associated with inadvertent contact with electrical energized parts/components within the enclosure 90 if energized during normal device operation (e.g., operation of external electrical monitoring device 110). In this regard, the enclosure 90 may provide safety/shielding protection associated with a user (e.g., an operator) utilizing/handling the enclosure 90. The non-metallic material of the enclosure 90 may include for example, but is not limited to, fiberglass, plastic, polymer-based materials, silicone, etc. The non-metallic material may provide a number of advantages, including facilitating easy operator handling (e.g., a lightweight enclosure 90), electrical hazard protection, and/or electromagnetic field (EMF) protection. The enclosure 90 may be configured to reduce electromagnetic interference within the enclosure 90. For example, the enclosure 90 may be configured to reduce the electromagnetic interference within the enclosure 90 by a predetermined threshold. In some example embodiments, the enclosure 90 may be constructed from fiberglass (e.g., as the non-metallic material). In one example embodiment, the enclosure 90 (e.g., a fiberglass enclosure) may have dimensions such as for example 9.45 x 6.30 x 4.72 inches. In other example embodiments, the enclosure 90 may have any other suitable dimensions. In some other example embodiments, the enclosure 90 may comply with National Electrical Manufacturers Association (NEMA) standards.

The external electrical monitoring device 110 may comprise an electrical power quality meter 2 such as, for example, a data logger power meter device (e.g., a 4-pole, 5-wire connection). Moreover, the external electrical monitoring device 110 may comprise a plurality of voltage and/or current transducers (e.g., transformers 5). Furthermore, the external electrical monitoring device 110 may comprise one or more communication ports (e.g., port 112, port 114). In this regard, the enclosure 90 may embody the electrical power quality meter 2 which comprises the transducers (e.g., transformers 5), communication ports (e.g., ports 112, 114), fuse holders 6, fuses 7 and any other suitable components of the external electrical monitoring device 110. The external electrical monitoring device 110 may be connected to two rapid flanged receptacles such as, for example, a 480 volts of alternating current (VAC) Flanged Male Receptacle and a 480 VAC Flanged Female Receptacle.

In an example embodiment, the external electrical monitoring device 110 may comprise transformers 5 (e.g., current and/or voltage transformers), for example, 35 amp current transformers, one or more fuse holders 6 (e.g., three 30A-600V in-line fuse holders), one or more fuses 7 (e.g., three 30 amp / 600 volt in-line fuses), at least one communication port (e.g., port 112, port 114, such as, for example ethernet ports) (e.g., an ethernet bulkhead adapter), a cable 11 such as, for example, an ethernet cable (e.g., a 6″ ethernet patch cable), a cord grip connector 13 (e.g., a cord grip connector for 120 VAC cord), and a control power cord 14 (e.g., a 120 VAC pigtail cord).

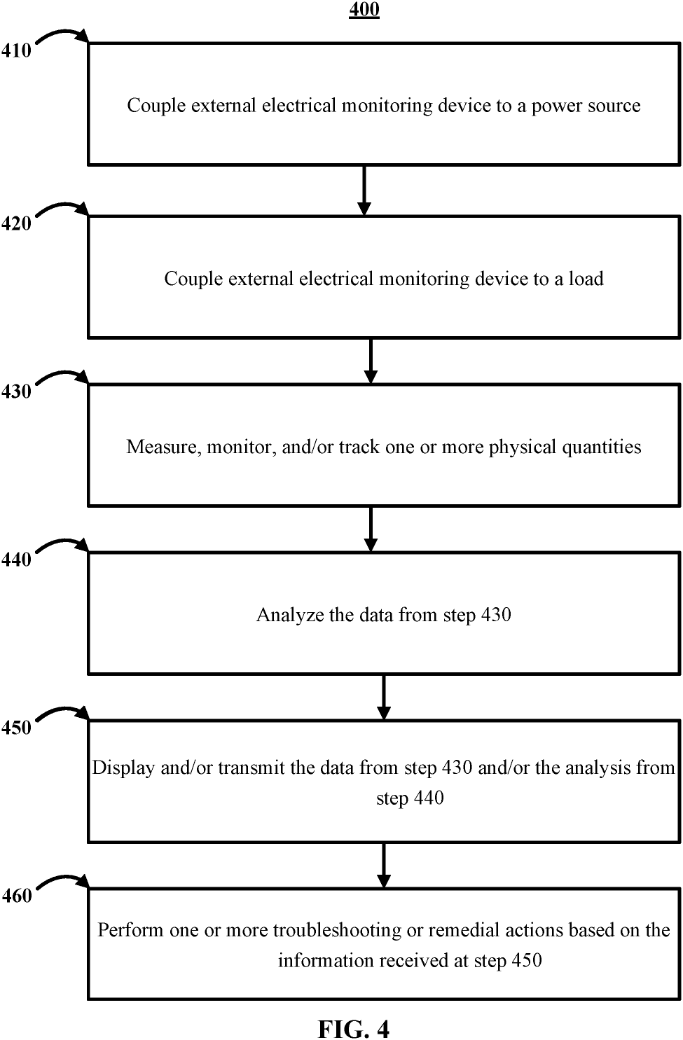

FIG. 4 illustrates an example method 400 for monitoring and/or troubleshooting electrical power. Method 400 may begin at step 410, where an external electrical monitoring device (e.g., external electrical monitoring device 110) may be coupled to a power source (e.g., power source 300). For example, the coupling to the power source may comprise plugging an input electrical connection of the external electrical monitoring device (e.g., input electrical connection 120) into a tap box electrical connector. The external electrical monitoring device 110, a plurality of electrical ports (e.g., the input electrical connection, the tap box electrical connector), a power line (e.g., power source 300) and/or other suitable components may be embodied within an enclosure 90. The enclosure 90 may be a non-metallic enclosure including for example, but not limited to, plastic, polymer-based materials, silicone, etc. The enclosure 90 may be configured to reduce electromagnetic interference within the enclosure 90. For example, the enclosure 90 may be configured to reduce the electromagnetic interference within the enclosure 90 by a predetermined threshold. In order to promote electrical safety and ease of connection, the external electrical monitoring device may be inspected, tested, and safety certified by one or more recognized independent laboratories or organizations to ensure electrical safety compliance (e.g., by Underwriters’ Laboratories (UL)). Moreover, in some exemplary embodiments coupling the external electrical monitoring device to the power source may require no manual connections (e.g., exposure to bare wires, breakers, etc.).

At step 420, the external electrical monitoring device may be coupled to a load (e.g., load 140), such as a server rack. For example, coupling to the load may comprise plugging an electrical connection associated with the load (e.g., a power cord of a server rack) into an output electrical connection (e.g., output electrical connection 150) of the external electrical monitoring device. Moreover, in order to promote electrical safety and ease of connection, coupling the external electrical monitoring device to the load may, in some example embodiments, require no manual connections (e.g., exposure to bare wires, breakers, etc.).

At step 430, the external electrical monitoring device may receive, measure, monitor, and/or track one or more physical quantities (e.g., of physical environment 100) associated with the power source coupled to the external electrical monitoring device at step 410 and/or the load coupled to the external electrical monitoring device at step 420. For example, the external electrical monitoring device may measure, monitor, and/or track one or more of input and/or output electrical voltage, current, frequency, power (e.g., power summary, power demand, power factor, harmonic distortion, etc.), and/or energy (e.g., energy total, energy delivered, energy received, energy consumed, etc.). Moreover, the external electrical monitoring device may determine instantaneous, average, minimum, and/or maximum values for a current point in time, a specified time duration, or a specified time period.

At step 440, the external electrical monitoring device may analyze the data associated with step 430. For example, the external electrical monitoring device may determine trends and/or forecast energy demand or other measured parameters, such as voltage, current, frequency power factor, active, reactive power, average and per phase measurements, apparent power & harmonics. Moreover, the external electrical monitoring device may use metering and/or other alarm conditions to identify and/or report events associated with the conditions. In some example embodiments, the reported events may be associated with faults (e.g., electrical faults). For example, one or more faults (e.g., breaker failure, conductor failure, component overheating, and/or server rack component failure) may be detected based on determining a measured or calculated parameter exceeds a predetermined threshold. Detected faults may include, but are not limited to, no voltage (e.g., open circuit), voltage/current imbalance (e.g., excessive current or minimal current, harmonics, ground current and any power quality disturbance), phase(s) lost, phase sequence, voltage sag, voltage swell, harmonic distortion, waveform capture and/or meter events.

At step 450, the external electrical monitoring device may display and/or transmit the data associated with step 430 and/or the analysis associated with step 440. For example, the external electrical monitoring device may comprise a display and may present information to a user via the display. In another example embodiment, the external electrical monitoring device may comprise a communication channel to one or more external systems (e.g., user device 170 and/or server 180 via network 160) to transmit the data associated with step 430.

At step 460, one or more troubleshooting or remedial actions may be performed based on the information received at step 450. For example, all phases for current loading may be identified for a current imbalance by identifying an imbalance of greater than +-10% between phases for individual phases. Open circuit faults may be associated with overcurrent protection device failure or issues with a power connection to the rack. Harmonics faults may be associated with load or line power supply switching issues.

One or more troubleshooting actions (e.g., continuity checks and specific voltage measurements) may utilize enhanced metering and measurement devices to confirm one or more issues identified by the electrical monitoring device 110. Remedial actions may include, but are not limited to, isolating power to a circuit (e.g., by opening an overcurrent protection device), disconnecting power cords, and/or performing a lock out tag out procedure. For example, a user may replace a tap box electrical connector and/or a server rack component based on information received at step 450. In some example embodiments, the information received at step 450 may denote a fault condition (e.g., an electrical fault or a measured or calculated parameter exceeding a predetermined threshold, breaker failure, conductor failure, component overheating and or server rack component failure) and the remedial action(s) may be associated with addressing the fault condition.

Some example embodiments may repeat one or more steps of the method of FIG. 4, where appropriate. Although this disclosure describes and illustrates particular steps of the method of FIG. 4 as occurring in a particular order, this disclosure contemplates any suitable steps of the method of FIG. 4 occurring in any suitable order. Moreover, although this disclosure describes and illustrates an example method for monitoring and/or troubleshooting electrical power including the particular steps of the method of FIG. 4, this disclosure contemplates any suitable method for monitoring and/or troubleshooting electrical power including any suitable steps, which may include all, some, or none of the steps of the method of FIG. 4, where appropriate. Furthermore, although this disclosure describes and illustrates particular components, devices, or systems carrying out particular steps of the method of FIG. 4, this disclosure contemplates any suitable combination of any suitable components, devices, or systems carrying out any suitable steps of the method of FIG. 4.

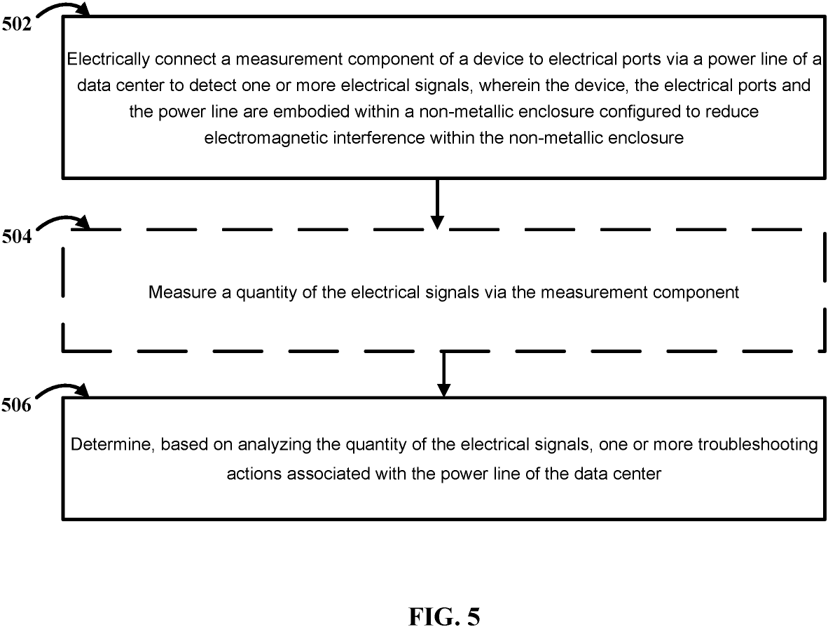

FIG. 5 illustrates an example flowchart illustrating operations for a device performing electrical power monitoring and analysis according to an exemplary embodiment. At operation 502, a device (e.g., external electrical monitoring device 110) may electrically connect a measurement component of the device to electrical ports via a power line of a data center to detect one or more electrical signals. The device, the electrical ports and the power line may be embodied within a non-metallic enclosure configured to reduce electromagnetic interference within the non-metallic enclosure.

Optionally, at operation 504, a device (e.g., external electrical monitoring device 110) may enable measuring of a quantity of the electrical signals via the measurement component. At operation 506, a device (e.g., external electrical monitoring device 110) may determine, based on analyzing the quantity of the electrical signals, one or more troubleshooting actions associated with the power line of the data center.

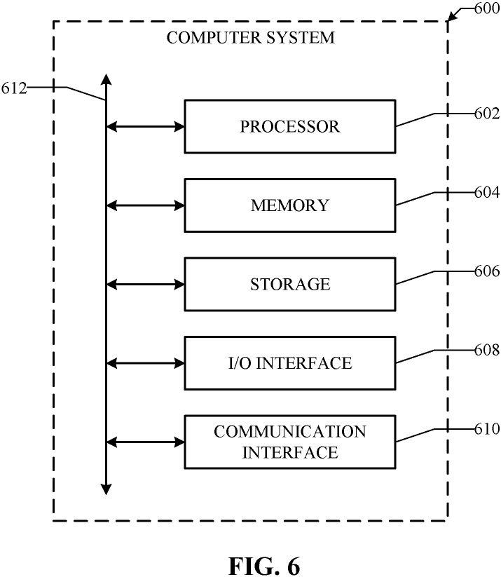

FIG. 6 illustrates an example computer system 600. In particular exemplary embodiments, one or more computer systems 600 perform one or more steps of one or more methods described or illustrated herein. In particular exemplary embodiments, one or more computer systems 600 provide functionality described or illustrated herein. In particular exemplary embodiments, software running on one or more computer systems 600 performs one or more steps of one or more methods described or illustrated herein or provides functionality described or illustrated herein. Particular embodiments may include one or more portions of one or more computer systems 600. Herein, reference to a computer system may encompass a computing device, and vice versa, where appropriate. Moreover, reference to a computer system may encompass one or more computer systems, where appropriate.

This disclosure contemplates any suitable number of computer systems 600. This disclosure contemplates computer system 600 taking any suitable physical form. As example and not by way of limitation, computer system 600 may be an embedded computer system, a system-on-chip (SOC), a single-board computer system (SBC) (such as, for example, a computer-on-module (COM) or system-on-module (SOM)), a desktop computer system, a laptop or notebook computer system, an interactive kiosk, a mainframe, a mesh of computer systems, a mobile telephone, a personal digital assistant (PDA), a server, a tablet computer system, an augmented/virtual reality device, or a combination of two or more of these. Where appropriate, computer system 600 may include one or more computer systems 600; be unitary or distributed; span multiple locations; span multiple machines; span multiple data centers; or reside in a cloud, which may include one or more cloud components in one or more networks. Where appropriate, one or more computer systems 600 may perform without substantial spatial or temporal limitation one or more steps of one or more methods described or illustrated herein. As an example and not by way of limitation, one or more computer systems 600 may perform in real time or in batch mode one or more steps of one or more methods described or illustrated herein. One or more computer systems 600 may perform at different times or at different locations one or more steps of one or more methods described or illustrated herein, where appropriate.

In particular exemplary embodiments, computer system 600 includes a processor 602, memory 604, storage 606, an input/output (I/O) interface 608, a communication interface 610, and a bus 612. Although this disclosure describes and illustrates a particular computer system having a particular number of particular components in a particular arrangement, this disclosure contemplates any suitable computer system having any suitable number of any suitable components in any suitable arrangement.

In particular exemplary embodiments, processor 602 includes hardware for executing instructions, such as those making up a computer program. As an example and not by way of limitation, to execute instructions, processor 602 may retrieve (or fetch) the instructions from an internal register, an internal cache, memory 604, or storage 606; decode and execute them; and then write one or more results to an internal register, an internal cache, memory 604, or storage 606. In particular exemplary embodiments, processor 602 may include one or more internal caches for data, instructions, or addresses. This disclosure contemplates processor 602 including any suitable number of any suitable internal caches, where appropriate. As an example and not by way of limitation, processor 602 may include one or more instruction caches, one or more data caches, and one or more translation lookaside buffers (TLBs). Instructions in the instruction caches may be copies of instructions in memory 604 or storage 606, and the instruction caches may speed up retrieval of those instructions by processor 602. Data in the data caches may be copies of data in memory 604 or storage 606 for instructions executing at processor 602 to operate on; the results of previous instructions executed at processor 602 for access by subsequent instructions executing at processor 602 or for writing to memory 604 or storage 606; or other suitable data. The data caches may speed up read or write operations by processor 602. The TLBs may speed up virtual-address translation for processor 602. In particular exemplary embodiments, processor 602 may include one or more internal registers for data, instructions, or addresses. This disclosure contemplates processor 602 including any suitable number of any suitable internal registers, where appropriate. Where appropriate, processor 602 may include one or more arithmetic logic units (ALUs); be a multi-core processor; or include one or more processors 602. Although this disclosure describes and illustrates a particular processor, this disclosure contemplates any suitable processor.

In particular exemplary embodiments, memory 604 includes main memory for storing instructions (e.g., encoded in memory 604), for processor 602 to execute or data for processor 602 to operate on. As an example and not by way of limitation, computer system 600 may load instructions from storage 606 or another source (such as, for example, another computer system 600) to memory 604. Processor 602 may then load the instructions from memory 604 to an internal register or internal cache. To execute the instructions, processor 602 may retrieve the instructions from the internal register or internal cache and decode them. During or after execution of the instructions, processor 602 may write one or more results (which may be intermediate or final results) to the internal register or internal cache. Processor 602 may then write one or more of those results to memory 604. In particular exemplary embodiments, processor 602 may execute instructions in one or more internal registers or internal caches or in memory 604 (as opposed to storage 606 or elsewhere) and operates on data in one or more internal registers or internal caches or in memory 604 (as opposed to storage 606 or elsewhere). One or more memory buses (which may each include an address bus and a data bus) may couple processor 602 to memory 604. Bus 612 may include one or more memory buses, as described below. In particular exemplary embodiments, one or more memory management units (MMUs) may reside between processor 602 and memory 604 and may facilitate accesses to memory 604 requested by processor 602. In particular exemplary embodiments, memory 604 includes random access memory (RAM). This RAM may be volatile memory, where appropriate Where appropriate, this RAM may be dynamic RAM (DRAM) or static RAM (SRAM). Moreover, where appropriate, this RAM may be single-ported or multi-ported RAM. This disclosure contemplates any suitable RAM. Memory 604 may include one or more memories 604, where appropriate. Although this disclosure describes and illustrates particular memory, this disclosure contemplates any suitable memory.

In particular exemplary embodiments, storage 606 includes mass storage for data or instructions. As an example and not by way of limitation, storage 606 may include a hard disk drive (HDD), a floppy disk drive, flash memory, an optical disc, a magneto-optical disc, magnetic tape, or a Universal Serial Bus (USB) drive or a combination of two or more of these. Storage 606 may include removable or non-removable (or fixed) media, where appropriate. Storage 606 may be internal or external to computer system 600, where appropriate. In particular exemplary embodiments, storage 606 is non-volatile, solid-state memory. In particular exemplary embodiments, storage 606 includes read-only memory (ROM). Where appropriate, this ROM may be mask-programmed ROM, programmable ROM (PROM), erasable PROM (EPROM), electrically erasable PROM (EEPROM), electrically alterable ROM (EAROM), or flash memory or a combination of two or more of these. This disclosure contemplates mass storage 606 taking any suitable physical form. Storage 606 may include one or more storage control units facilitating communication between processor 602 and storage 606, where appropriate. Where appropriate, storage 606 may include one or more storages 606. Although this disclosure describes and illustrates particular storage, this disclosure contemplates any suitable storage.

In particular exemplary embodiments, I/O interface 608 includes hardware, software, or both, providing one or more interfaces for communication between computer system 600 and one or more I/O devices. Computer system 600 may include one or more of these I/O devices, where appropriate. One or more of these I/O devices may enable communication between a person and computer system 600. As an example and not by way of limitation, an I/O device may include a keyboard, keypad, microphone, monitor, mouse, printer, scanner, speaker, still camera, stylus, tablet, touch screen, trackball, video camera, another suitable I/O device or a combination of two or more of these. An I/O device may include one or more sensors. This disclosure contemplates any suitable I/O devices and any suitable I/O interfaces 608 for them. Where appropriate, I/O interface 608 may include one or more device or software drivers enabling processor 602 to drive one or more of these I/O devices. I/O interface 608 may include one or more I/O interfaces 608, where appropriate. Although this disclosure describes and illustrates a particular I/O interface, this disclosure contemplates any suitable I/O interface.

In particular exemplary embodiments, communication interface 610 includes hardware, software, or both providing one or more interfaces for communication (such as, for example, packet-based communication) between computer system 600 and one or more other computer systems 600 or one or more networks. As an example and not by way of limitation, communication interface 610 may include a network interface controller (NIC) or network adapter for communicating with an Ethernet or other wire-based network or a wireless NIC (WNIC) or wireless adapter for communicating with a wireless network, such as a WI-FI network. This disclosure contemplates any suitable network and any suitable communication interface 610 for it. As an example and not by way of limitation, computer system 600 may communicate with an ad hoc network, a personal area network (PAN), a local area network (LAN), a wide area network (WAN), a metropolitan area network (MAN), or one or more portions of the Internet or a combination of two or more of these. One or more portions of one or more of these networks may be wired or wireless. As an example, computer system 600 may communicate with a wireless PAN (WPAN) (such as, for example, a BLUETOOTH WPAN), a WI-FI network, a WI-MAX network, a cellular telephone network (such as, for example, a Global System for Mobile Communications (GSM) network), or other suitable wireless network or a combination of two or more of these. Computer system 600 may include any suitable communication interface 610 for any of these networks, where appropriate. Communication interface 610 may include one or more communication interfaces 610, where appropriate. Although this disclosure describes and illustrates a particular communication interface, this disclosure contemplates any suitable communication interface.

In particular exemplary embodiments, bus 612 includes hardware, software, or both coupling components of computer system 600 to each other. As an example and not by way of limitation, bus 612 may include an Accelerated Graphics Port (AGP) or other graphics bus, an Enhanced Industry Standard Architecture (EISA) bus, a front-side bus (FSB), a HYPERTRANSPORT (HT) interconnect, an Industry Standard Architecture (ISA) bus, an INFINIBAND interconnect, a low-pin-count (LPC) bus, a memory bus, a Micro Channel Architecture (MCA) bus, a Peripheral Component Interconnect (PCI) bus, a PCI-Express (PCIe) bus, a serial advanced technology attachment (SATA) bus, a Video Electronics Standards Association local (VLB) bus, or another suitable bus or a combination of two or more of these. Bus 612 may include one or more buses 612, where appropriate. Although this disclosure describes and illustrates a particular bus, this disclosure contemplates any suitable bus or interconnect.

Herein, a computer-readable non-transitory storage medium or media may include one or more semiconductor-based or other integrated circuits (ICs) (such, as for example, field-programmable gate arrays (FPGAs) or application-specific ICs (ASICs)), hard disk drives (HDDs), hybrid hard drives (HHDs), optical discs, optical disc drives (ODDs), magneto-optical discs, magneto-optical drives, floppy diskettes, floppy disk drives (FDDs), magnetic tapes, solid-state drives (SSDs), RAM-drives, SECURE DIGITAL cards or drives, any other suitable computer-readable non-transitory storage media, or any suitable combination of two or more of these, where appropriate. A computer-readable non-transitory storage medium may be volatile, non-volatile, or a combination of volatile and non-volatile, where appropriate.

Herein, “or” is inclusive and not exclusive, unless expressly indicated otherwise or indicated otherwise by context. Therefore, herein, “A or B” means “A, B, or both,” unless expressly indicated otherwise or indicated otherwise by context. Moreover, “and” is both joint and several, unless expressly indicated otherwise or indicated otherwise by context. Therefore, herein, “A and B” means “A and B, jointly or severally,” unless expressly indicated otherwise or indicated otherwise by context.

The scope of this disclosure encompasses all changes, substitutions, variations, alterations, and modifications to the example embodiments described or illustrated herein that a person having ordinary skill in the art would comprehend. The scope of this disclosure is not limited to the example embodiments described or illustrated herein. Moreover, although this disclosure describes and illustrates respective embodiments herein as including particular components, elements, feature, functions, operations, or steps, any of these embodiments may include any combination or permutation of any of the components, elements, features, functions, operations, or steps described or illustrated anywhere herein that a person having ordinary skill in the art would comprehend. Furthermore, reference in the appended claims to an apparatus or system or a component of an apparatus or system being adapted to, arranged to, capable of, configured to, enabled to, operable to, or operative to perform a particular function encompasses that apparatus, system, component, whether or not it or that particular function is activated, turned on, or unlocked, as long as that apparatus, system, or component is so adapted, arranged, capable, configured, enabled, operable, or operative. Additionally, although this disclosure describes or illustrates particular embodiments as providing particular advantages, particular embodiments may provide none, some, or all of these advantages.

What is claimed:

1. A method comprising:
electrically connecting a measurement component of an electrical device to a plurality of electrical ports via a power line of a data center to detect one or more electrical signals, wherein the electrical device, the plurality of electrical ports and the power line are embodied within a non-metallic enclosure configured to reduce electromagnetic interference within the non-metallic enclosure;
measuring a quantity of the electrical signals via the measurement component; and
determining, based on analyzing the quantity of the electrical signals, one or more troubleshooting actions associated with the power line of the data center.

2. The method of claim 1, wherein the electrical device comprises a compatible plug associated with the power line of the data center and electrically connecting the measurement component of the electrical device to the electrical ports via the power line of the data center comprises connecting the compatible plug to the power line of the data center.

3. The method of claim 1, further comprising communicating, by the electrical device to one or more remote devices, an indication of the quantity of the electrical signals.

4. The method of claim 3, further comprising causing performing of the one or more troubleshooting actions based on detecting that the indication of the quantity exceeds a predetermined threshold.

5. The method of claim 1, wherein the electrical device is safety certified for electrical safety compliance.

6. The method of claim 1, wherein the enclosure comprises a fiberglass enclosure configured to reduce the electromagnetic interference within the fiberglass enclosure by a predetermined threshold.

7. The method of claim 1, wherein the electrical device comprises a data logger power meter device, a plurality of voltage and current transducers, and a communication port.

8. A system comprising:
a device comprising one or more processors; and
at least one memory storing instructions, that when executed by the one or more processors, cause the device to:
measure, by a measurement component of the device, a quantity of one or more electrical signals, wherein the measurement component of the device is electrically connected to a plurality of electrical ports via a power line of a data center to detect the one or more electrical signals, wherein the device, the plurality of electrical ports and the power line are embodied within a fiberglass enclosure configured to reduce electromagnetic interference within the fiberglass enclosure; and
determine, based on analyzing the quantity of the electrical signals, one or more troubleshooting actions associated with the power line of the data center.

9. The system of claim 8, wherein the device comprises a compatible plug with the power line of the data center and wherein the measurement component of the device is electrically connected to the plurality of electrical ports via the power line of the data center by connecting the compatible plug to the power line of the data center.

10. The system of claim 8, wherein when the one or more processors further execute the instructions, the device is configured to communicate with one or more remote devices, an indication of the quantity of the electrical signals.

11. The system of claim 10, wherein when the one or more processors further execute the instructions, the device is configured to cause performing of the one or more troubleshooting actions based on detecting that the indication of the quantity exceeds a predetermined threshold.

12. The system of claim 8, wherein when the one or more processors further execute the instructions, the device is configured to facilitate modifying of at least one connected equipment component based on the one or more troubleshooting actions.

13. The system of claim 8, wherein the quantity of the electrical signals is measured over a period of time, and wherein the fiberglass enclosure is configured to reduce the electromagnetic interference within the fiberglass enclosure by a predetermined threshold.

14. The system of claim 8, wherein the device is safety certified for electrical safety compliance.

15. A computer program product comprising a computer readable storage medium having instructions encoded thereon which, when executed by a processor, cause:
measuring, by a measurement component of an electrical device, a quantity of one or more electrical signals, wherein the measurement component of the electrical device is electrically connected to a plurality of electrical ports via a power line of a data center to detect the one or more electrical signals, wherein the electrical device, the plurality of electrical ports and the power line are embodied within a non-metallic enclosure configured to reduce electromagnetic interference within the non-metallic enclosure; and
determining, based on analyzing the quantity of the electrical signals, one or more troubleshooting actions associated with the power line of the data center.

16. The computer program product of claim 15, wherein the electrical device comprises a compatible plug associated with the power line of the data center and electrically connecting the measurement component of the electrical device to the electrical ports via the power line of the data center comprises connecting the compatible plug to the power line of the data center.

17. The computer program product of claim 15, wherein the computer readable storage medium further comprises instructions encoded thereon which, when executed by the processor, cause:
communicating, by the electrical device to one or more remote devices, an indication of the quantity of the electrical signals.

18. The computer program product of claim 17, wherein the computer readable storage medium further comprises instructions encoded thereon which, when executed by the processor,cause:
performing of the one or more troubleshooting actions based on detecting that the indication of the quantity exceeds a predetermined threshold.

19. The computer program product of claim 15, wherein the computer readable storage medium further comprises instructions encoded thereon which, when executed by the processor, cause:
modifying at least one equipment component connected to the measurement component based on the one or more troubleshooting actions.

20. The computer program product of claim 15, wherein the electrical device is safety certified for electrical safety compliance, and wherein the enclosure comprises a fiberglass enclosure configured to reduce the electromagnetic interference within the fiberglass enclosure by a predetermined threshold.
